(19) United States
(12) Patent Application Publication
(10) Pub. No.: US 2008/0309320 A1
(43) Pub. Date: Dec. 18, 2008

(54) NEGATIVE VOLTAGE DETECTION CIRCUIT FOR SYNCHRONOUS RECTIFIER MOSFET

(75) Inventors: HUNG SUNG CHU, TAINAN COUNTY (TW); SHEN YAO LIANG, TAINAN COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: HIMAX TECHNOLOGIES LIMITED, TAINAN COUNTY (TW)

(21) Appl. No.: 12/103,596

(22) Filed: Apr. 15, 2008

(30) Foreign Application Priority Data
Jun. 13, 2007 (TW) 096121267

(51) Int. Cl. G01R 19/22

(52) U.S. Cl. 324/119

(57) ABSTRACT

A negative voltage detection circuit for a synchronous rectifier metal oxide silicon field effect transistor (MOSFET). The circuit comprises a reference current source, a first circuit mirroring a first current based upon the reference current source and generating a first voltage based upon a detection voltage, a second circuit mirroring a second current based upon the reference current source and generating a second voltage, and a comparator having input ends to receive the first voltage and the second voltage, wherein a level of an output voltage of the comparator changes when the detection voltage is equivalent to a value predetermined according to a difference between the first current and the second current.

### BACKGROUND OF THE INVENTION

1. Field of the Invention

The present invention relates to a negative voltage detection circuit, and more particularly to a negative voltage detection circuit for a synchronous rectifier MOSFET.

2. Description of the Related Art

FIG. 1 shows a conventional synchronous rectifier MOSFET circuit 10. A synchronous control circuit 100 is electrically connected to a gate 120b of a power transistor 120, so as to switch on or switch off the power transistor 120 by using an output control signal A. A parasitic body diode 121 exists between the drain 120a and the source 120c of the power transistor 120. The power transistor 120 has the advantages of a fast switching speed and a low turn-on resistance between the drain 120a and the source 120c, thus reducing the power consumption when the power transistor 120 is turned on.

During a positive half-cycle of an AC input signal D, an input synchronous signal C of the synchronous control circuit 100 is at a logic high level, and a current flows from the drain to the source of the power transistor 120, as indicated by an arrow I. The synchronous control circuit 100 determines the logic level of the output control signal A according to the input synchronous signal C and a feedback voltage signal B. Due to an extremely high input impedance of the synchronous control circuit 100, the current passing through a resistor 107 for noise reduction is small enough to be ignored. Therefore, the feedback voltage signal B can be considered the same as an output voltage V_{P} of the source 120c of the power transistor 120.

For the discontinuous current mode (DCM), only a small current flows through the power transistor 120 near the end of the positive half-cycle of the input signal D, which results in a small output negative voltage value of the source 120c of the power transistor 120 due to the small turn-on resistance of the power transistor 120. On one hand, if the synchronous control circuit 100 fails to turn off the power transistor 120 by the output control signal A in time, a reverse current flowing from the source to the drain of the power transistor 120 will occur and discharge the capacitor. This will adversely result in a voltage drop of the output voltage V_{P} of the synchronous rectifier MOSFET circuit 10. On the other hand, if the power transistor 120 is turned off before the current I induced by the input signal D during the positive-half cycle completely flows out, the power-saving efficiency will be greatly degraded.

In view of the above, it is crucial to turn off the power transistor 120 in time to maintain normal operation of the synchronous rectifier MOSFET circuit 10 and to obtain a high power saving efficiency. This will be achieved upon a precise detection mechanism for the value of the output voltage V_{P}.

### SUMMARY OF THE INVENTION

An objective of the present invention is to provide a negative voltage detection circuit for a synchronous rectifier MOSFET, capable of precisely detecting a small negative voltage.

The negative voltage detection circuit provided by the present invention comprises a reference current source, a first circuit, a second circuit, and a comparator, wherein the reference current source, the first circuit, and the second circuit form a current mirror structure.

The reference current source comprises a first transistor, a second transistor, an operational amplifier and a resistor. The input voltage of an input end of the operational amplifier is a bandgap type reference voltage, and a stable voltage source is provided to so that the reference current source provides a stable reference current. The output end of the operational amplifier is connected to the gate of the first transistor. The first transistor, the second transistor, and the resistor are connected in series, wherein the resistor together with the operational amplifier generates the reference current.

The first circuit and the second circuit respectively comprise an operational transistor and a load transistor circuit connected in series. The load transistor circuits of the first and the second circuit are both formed by a plurality of transistors connected in parallel. The number of the load transistors of the first circuit connected in parallel is different from that of the second circuit, such that the first circuit and the second circuit respectively mirror a first current and a second current different from each other based on the reference current source.

The gate of the operational transistor of the first circuit is connected to a voltage detection point through a resistor for blocking noises, the drain of which is grounded, and the source is electrically connected to an input end of the comparator, wherein a first voltage is supplied by the input end of the comparator. The gate and drain of the operational transistor of the second circuit are grounded, and the source thereof is electrically connected to another input end of the comparator, wherein a second voltage is supplied by the input end of the comparator.

When the detection voltage of the voltage detection point approaches from a negative value to 0 V and is equal to a predetermined value, the logic level of the output end of the comparator changes.

### BRIEF DESCRIPTION OF THE DRAWINGS

The invention will be described according to the appended drawings in which:

FIG. 1 is a schematic view of a conventional synchronous rectifier MOSFET application circuit;

FIG. 2 is a schematic view of the negative voltage detection circuit for a synchronous rectifier MOSFET in accordance with an embodiment of the present invention; and

FIG. 3 is a schematic view of the logic level transition of the output voltage of the comparator in accordance with an embodiment of the present invention.

### DETAILED DESCRIPTION OF THE INVENTION

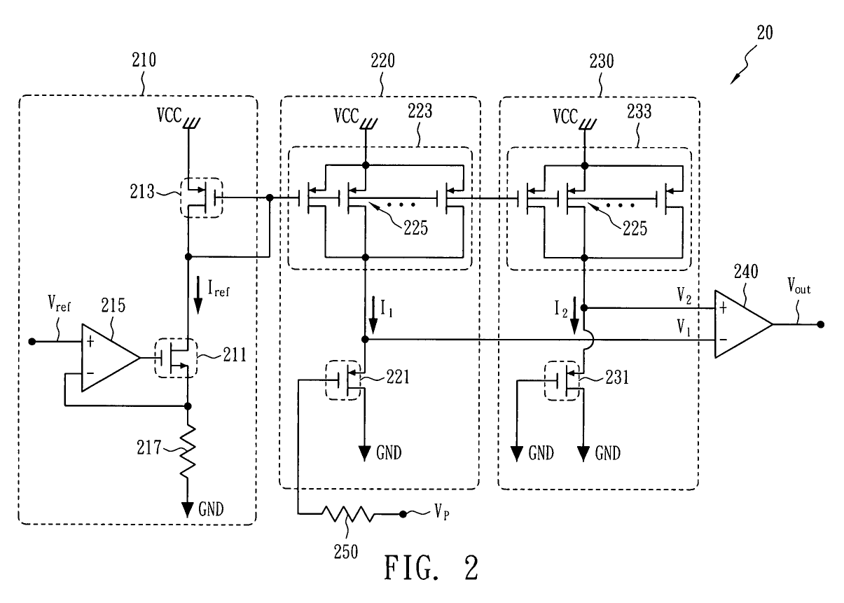

FIG. 2 shows a negative voltage detection circuit 20 for a synchronous rectifier MOSFET in accordance with an embodiment of the present invention. The negative voltage detection circuit 20 comprises a reference current source 210, a first circuit 220, a second circuit 230, and a comparator 240. The reference current source 210, the first circuit 220, and the second circuit 230 form a current mirror structure, wherein the transistors are FETs.

The reference current source 210 comprises a first transistor 211 (an NMOS type operational transistor), a second transistor 213 (a PMOS type load transistor), an operational amplifier 215, and a resistor 217. The first transistor 211, the second transistor 213, and the resistor 217 are connected in series. The input voltage at the positive input end of the operational amplifier 215 is a bandgap type reference voltage V_{ref} which does not change along with the external environmental temperature so that the reference current source 210 generates a stable reference current I_{ref}. The negative input end of the operational amplifier 215, the source of the first transistor 211, and the resistor 217 are electrically connected together. The value of the current passing through the resistor 217 equals the reference voltage V_{ref} divided by the resistance value of the resistor 217. The reference current I_{ref} can be regarded as the current passing through the resistor 217.

The first circuit 220 comprises an operational transistor 221 (PMOS type) and a load transistor circuit 223 which are connected in series. The load transistor circuit 223 is formed by M load transistors 225 (PMOS type) connected in parallel. Each of the load transistors 225 is a PMOS transistor and the same as the second transistor 213 of the reference current source 210. Therefore, the first circuit 220 mirrors a first current I₁ based upon the reference current source 210, and the first current I₁ is approximately M times the reference current I_{ref}.

The second circuit 230 comprises an operational transistor 231 (PMOS type) and a load transistor circuit 233 which are connected in series. The load transistor circuit 233 is formed by N load transistors 225 connected in parallel. Each of the load transistors 225 is a PMOS transistor and the same as the second transistor 213 of the reference current source 210. Therefore, the second circuit 230 mirrors a second current I₂ from the reference current source 210, and the second current I₂ is approximately N times the reference current I_{ref}, wherein M is larger than N so that the first current I₁ is larger than the second current I₂.

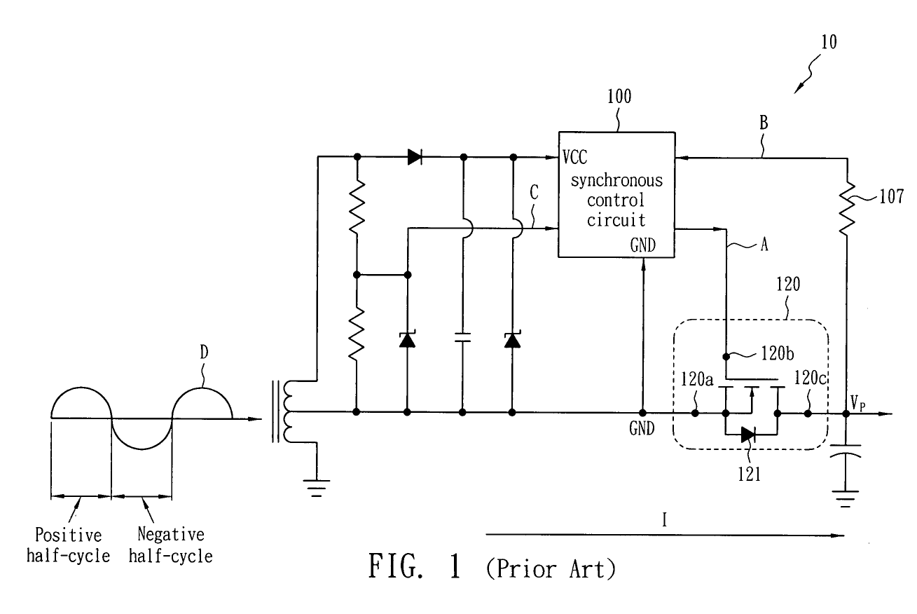

The gate of the operational transistor 221 is connected to receive the output voltage V_{P} of the source 120c of the power transistor 120 shown in FIG. 1 through a resistor 250 for noise reduction. The drain of the operational transistor 221 is grounded, and the source thereof is electrically connected to the negative input end of the comparator 240. The voltage V₁ at the negative input end of the comparator is approximately equal to the voltage |V_{gs1}| between the gate and source of the operational transistor 221 plus the detection voltage V_{P}, i.e., V₁=|V_{gs1}|+V_{P}. Thus, the value of V₁ varies along with the changes of the output voltage V_{P}.

The gate and drain of the operational transistor 231 are grounded, and the source thereof is electrically connected to the positive input end of the comparator 240. The voltage V₂ at the positive input end of the comparator 240 is the voltage |V_{gs2}| between the gate and the source of the operational transistor 231.

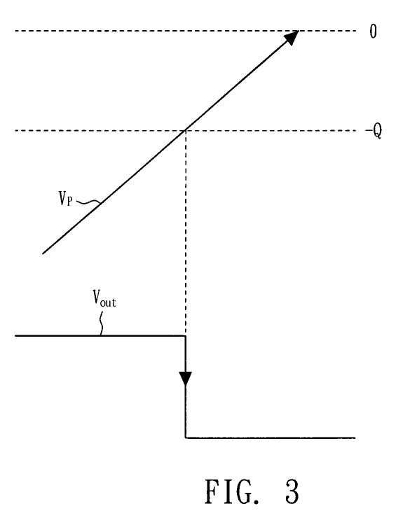

FIG. 3 shows the waveforms of the voltage signals V_{P} and Vₒᵤₜ. The level of voltage Vₒᵤₜ changes from a high logic level to a low logic level in order to turn off the power transistor when the voltage V_{P} reaches −Q, wherein −Q is the value of the voltage V_{P} which results in a value of the voltage V₁ equal to that of the voltage V₂, i.e., Q=|V_{gs2}|−|V_{gs1}|. Further, the first current I₁ and the second current I₂ can be obtained from the following formulas (1) and (2):

First Current I₁=M×I_{ref}=K₁(V_{gs1}−Vₜ₁)² (1)

Second Current I₂=N×I_{ref}=K₂(V_{gs2}−Vₜ₂)² (2)

where K₁ and K₂ are conductance parameters of the operational transistors 221 and 231, and Vₜ₁ and Vₜ₂ are pinch-off voltages thereof. As the operational transistors 221 and 231 are of the same transistor type, K₁=K₂, Vₜ₁=Vₜ₂. It can be deduced from formulas (1) and (2) that

$$\begin{matrix}Q = \vert {V}_{gs 2} \vert - \vert {V}_{gs 1} \vert \\ = ( \sqrt{{I}_{ref}} / \sqrt{{K}_{1}} ) \times ( \sqrt{M} - \sqrt{N} ) \\ = ( \sqrt{\frac{{I}_{1}}{{K}_{1}}} - \sqrt{\frac{{I}_{2}}{{K}_{1}}} ) .\end{matrix}$$

Therefore, the value Q can be selected according to the difference between the first current I₁ and the second current I₂, even if Q is a negative value close to 0. Moreover, the value Q is independent from the resistor 250 and not sensitive to the variation of I_{ref}.

The above-described embodiments of the present invention are intended to be illustrative only. Numerous alternative embodiments may be devised by persons skilled in the art without departing from the scope of the following claims.

What is claimed is:

1. A negative voltage detection circuit for a synchronous rectifier metal oxide silicon field effect transistor (MOSFET), comprising:
a reference current source;
a first circuit mirroring a first current based upon the reference current source and generating a first voltage based upon a detection voltage;
a second circuit mirroring a second current based upon the reference current source and generating a second voltage; and
a comparator having input ends to receive the first voltage and the second voltage, wherein a level of an output voltage of the comparator changes when the detection voltage is equivalent to a value predetermined according to a difference between the first current and the second current.

2. The negative voltage detection circuit for a synchronous rectifier MOSFET of claim 1, wherein the reference current source comprises:
a first transistor;
a second transistor;
an operational amplifier having a first input end receiving an input voltage acting as a reference voltage and an output end connected to the gate of the first transistor; and
a resistor generating a reference current accompanied by the operational amplifier;
wherein the first transistor, the second transistor and the resistor are connected in series, and a second input end of the operational amplifier, the source of the first transistor, and the resistor are electrically connected together.

3. The negative voltage detection circuit for a synchronous rectifier MOSFET of claim 2, wherein the reference voltage is a bandgap type reference voltage.

4. The negative voltage detection circuit for a synchronous rectifier MOSFET of claim 2, wherein the value of the reference current equals the reference voltage divided by the resistance value of the resistor.

5. The negative voltage detection circuit for a synchronous rectifier MOSFET of claim 2, wherein the first transistor is an NMOS transistor.

6. The negative voltage detection circuit for a synchronous rectifier MOSFET of claim 2, wherein the second transistor is a PMOS transistor.

7. The negative voltage detection circuit for a synchronous rectifier MOSFET of claim 2, wherein each of the first circuit and the second circuit comprises:
a load transistor circuit including a plurality of load transistors connected in parallel; and
an operational transistor connected in series with the load transistor circuit;
wherein the number of the load transistors of the first circuit connected in parallel is different from the number of the load transistors of the second circuit connected in parallel.

8. The negative voltage detection circuit for a synchronous rectifier MOSFET of claim 7, wherein the load transistors are substantially the same as the second transistor.

9. The negative voltage detection circuit for a synchronous rectifier MOSFET of claim 7, wherein the type of the operational transistor of the first circuit is the same as the type of the second circuit, and the number of the load transistors of the first circuit connected in parallel is larger than the number of the load transistors of the second circuit connected in parallel.

10. The negative voltage detection circuit for a synchronous rectifier MOSFET of claim 7, wherein the value of the first current is the product of multiplying the reference current by the number of the load transistors of the first circuit connected in parallel.

11. The negative voltage detection circuit for a synchronous rectifier MOSFET of claim 7, wherein the value of the second current is the product of multiplying the reference current by the number of the load transistors of the second circuit connected in parallel.

12. The negative voltage detection circuit for a synchronous rectifier MOSFET of claim 7, wherein the load transistors are PMOS transistors.

13. The negative voltage detection circuit for a synchronous rectifier MOSFET of claim 7, wherein the operational transistor is a PMOS transistor.

14. The negative voltage detection circuit for a synchronous rectifier MOSFET of claim 7, wherein the source of the operational transistor of the first circuit is electrically connected to the first voltage and the gate of the operational transistor of the first circuit is electrically connected to the detection voltage.

15. The negative voltage detection circuit for a synchronous rectifier MOSFET of claim 7, wherein the first voltage is the voltage between the source and the gate of the operational transistor of the first circuit plus the detection voltage.

16. The negative voltage detection circuit for a synchronous rectifier MOSFET of claim 7, wherein the source of the operational transistor of the second circuit is electrically connected to the second voltage, and the gate of the operational transistor of the second circuit is electrically connected to ground.

17. The negative voltage detection circuit for a synchronous rectifier MOSFET of claim 7, wherein the second voltage is the voltage between the gate and the source of the operational transistor of the second circuit.
